(19) United States
(12) Patent Application Publication
(10) Pub. No.: US 2004/0137698 A1
(43) Pub. Date: Jul. 15, 2004

(54) Fabrication system and method for monocrystaline semiconductor on a substrate

(76) Inventors: Gianni Taraschi, Somerville, MA (US); Eugene A. Fitzgerald, Windham, NH (US)

Correspondence Address: Matthew E. Connors, Gauthier & Connors LLP, 225 Franklin Street, Suite 3300, Boston, MA, 02110, US

(21) Appl. No.: 10/652,774

(22) Filed: Aug. 29, 2003

Related U.S. Application Data
(60) Provisional application No. 60/406,882, filed on Aug. 29, 2002.

(51) Int. Cl. H01L 21/30; H01L 21/46

(52) U.S. Cl. 438/458

(57) ABSTRACT

A method is disclosed for creating a transferred composite in accordance with an embodiment of the invention. The method includes the steps of depositing a buffer structure that on a first substrate; depositing a bonding structure including at least one layer of a strained semiconductor material on the buffer structure, wafer bonding the exposed surface of the bonding structure to a second substrate to form a wafer bonded pair; and removing the first substrate and at least a portion of the buffer structure. The layer of a strained semiconductor material has a thickness that is greater than the equilibrium critical thickness of said layer of strained semiconductor material, in accordance with an embodiment of the invention whereby the strained semiconductor layer is grown at low temperatures.

### PRIORITY

This application claims priority to U.S. Provisional Patent Application Ser. No. 60/406,882 filed Aug. 29, 2002.

### BACKGROUND OF THE INVENTION

The present invention relates to the fabrication of thin films for electronics, optoelectronics, and photonics applications, and relates in particular to the fabrication of thin films of monocrystalline silicon (Si), germanium (Ge), SiGe alloys, or combinations thereof (e.g., SiₓGe_{y}, where x and y may each be any number) on any desired substrate for electronics, optoelectronics or photonics applications.

It is desirable to fabricate a high-quality, monocrystalline, relaxed SiGe-on-insulator (SGOI) onto which a strained Si layer may be deposited, yielding strained Si-on-insulator (SSOI). Equivalently, SSOI substrates may also be fabricated such that the strained Si is directly on the insulating substrate, with no underlying relaxed SiGe layer.

The technique of separation-by-implanted-oxygen (SIMOX) is a popular method for the formation of SOI, but it is only applicable to SGOI fabrication for relatively low Ge content. This technique involves the implantation of oxygen ions to a desired depth, followed by a high temperature anneal to remove implant damage from the crystalline layer, and to form the buried oxide layer. The method has been successfully applied to SGOI for a Ge content of 18%. See S. Fukatsu, Y. Ishikawa, T. Saito and N. Shibata, SiGe-Based Semiconductor-On-Insulator Substrate Created by Low Energy Separation-by-Implanted-Oxygen, Applied Physics Letters, vol.72, no. 26, pp. 3485-3487 (1998). It has been discovered, however, that this technique is only applicable for Ge fractions less than 30%, due to the surface oxidation of SiGe and thermally induced instability of SiGe during post-implant annealing. See Y. Ishikawa, N. Shibata and S. Fukatsu, Factors Limiting the Composition Window for Fabrication of SiGe-on-Insulator Substrate by Low-Energy Oxygen Implantation, Thin-Solid-Films, vol.369, no.1-2, pp. 213-216 (2000).

Another method involves high temperature oxidation of a low Ge content SiGe layer on a thinned SOI substrate. See T. Tezuka, N. Sugiyama, T. Mizuno, M. Suzuki and S. Takagi, A Novel Fabrication Technique of Ultrathin and Relaxed SiGe Buffer Layers with High Ge Fraction for Sub-100 nm Strained Silicon-on-Insulator MOSFETS , Japanese Journal of Applied Physics, Part 1, vol.40, no. 4B, pp. 2866-2874 (2001); and T. Tezuka, N. Sugiyama, and S. Takagi, Fabrication of Strained Si on an Ultrathin SiGe-on-Insulator Virtual Substrate with a High Ge Fraction, Applied Physics Letters, vo.79, no. 12, pp.1798-1800 (2001). The oxidation causes the expulsion of Ge ahead of the oxide front, and the high temperature leads to Ge diffusion into the underlying thinned Si on the buried oxide. It is hoped that due to the high temperature, the buried oxide flows, and that the strain relaxation mechanism for the Ge-rich layer (forming due to Ge expulsion from the oxide) is lattice expansion and not misfit dislocation generation. On a wafer-scale, this may require that the relaxing film expand beyond the edge of the substrate. This approach is also plagued by high defect densities (˜10⁷ cm⁻²) when applied to blank wafers, and in certain applications places limits on the size of low defect areas via the use of micron-sized mesas (3 μm or less). See, for example, T. Tezuka, N. Sugiyama, S. Takagi and T. Kawakubo, Disclocation-free Formation of Relaxed SiGi-on-Insulator Layers, Applied Physics Letters, vol.80, no.19, pp.3560-2 (2002).

In addition to the above approaches, wafer bonding is another possible technique for the fabrication of SGOI or SSOI, where wafers with SiGe films on their surfaces are wafer bonded to insulating substrates, like oxidized Si wafers. Two general techniques exist for accomplishing layer transfer of a thin film material onto a desired substrate: grind/etch back, and delamination via implantation. In the grind/etch back method, the wafers are bonded, the backside of the wafer containing the transfer layer is thinned substantially via grinding, and an etch is used to remove the remaining excess material, leaving the transfer layer. The other method, delamination via implantation is described in U.S. Pat. No. 5,374,564 (to Izumi et al.). The Izumi et al. reference describes a process that involves hydrogen implantation prior to wafer bonding, followed by annealing to cause delamination and layer transfer. In both methods, a final chemical mechanical polishing step is often used to smooth and thin the transferred layer.

Other work has demonstrated the feasibility of wafer bonding for the creation of SGOI. For example, Electron Mobility Enhancement in Strained-Si n-Mosfets Fabricated on SiGe-on-Insulator (SGOI) Substrate by Z. Cheng, M. Currie, C. Leitz, G. Taraschi and E. Fitzgerald, IEEE Electron Device Letters, vol.22, no. 7, pp. 321-323 (2001) demonstrates SGOI fabrication using wafer bonding and grind/etchback, where the KOH etch employed stopped on the 20% Ge region of the relaxed SiGe graded layers. Chemical mechanical polishing (CMP) was then employed to both smooth and thin the transferred layer. Similarly, SiGe-on-Insulator Prepared by Wafer Bonding and Layer Transfer for High-Performance Field-Effect Transistors, by L. Huang, J. Chu, D. Canaperi, C. D'Emic, R. Anderson, S. Koester and H. Wong, Applied Physics Letters, vol.78, no. 9, pp. 1267-1269 (2001) discloses employing the technique of U.S. Pat. No. 5,374,564 to transfer SiGe, followed again by CMP to thin and smooth the transferred layer. The current limitation of these above methods is the lack of control over the final SiGe thickness transferred to the handle wafer, and the uniformity of the transferred layer across the wafer.

Generic approaches incorporating etch stop layer(s) have been proposed in U.S. Pat. No. 5,882,987 (to Srikrishnan), and U.S. Pat. No. 6,323,108 (to Kub et al.). These processes require that the ions are implanted at a depth below the etch stop layer. After wafer bonding and layer transfer via delamination, it is proposed that a selective etch can be used to remove material and stop on the etch stop. The approaches allow for uniform transferred layer thickness by employing an etch stop in conjunction with the technique of U.S. Pat. No. 5,374,564. Both works detailed above have been demonstrated within the context of Si layer transfer and not for low defect density, relaxed SiGe layer transfer. Neither work describes what type of etch stop or etches can be used to create SGOI or SSOI.

Published U.S. patent application Ser. No. 09/289,514 (Pub. No. 2001/0003269) disclosed a process for SGOI creation based on wafer bonding, combined with backside grinding, and a double etchback approach. See also, for example, G. Taraschi, Z. Cheng, M. Currie, C. Leitz, T. Langdo, M. Lee, A/Pitera, E. Fitzgerald, D. Antoniadis and J. Hoyt, Relaxed SiGe-on-Insulator Fabricated via Wafer Bonding and Layer Transfer: Etch-back and Smart-Cur Alternatives, 10^{th} International Symposium on Silicon-on-Insulator Technology and Devices, Washington D.C. (2001); and G. Taraschi, T. Langdo, M. Currie, E. Fitzgerald and D. Antoniadis, Relaxed SiGe-on-Insulator Fabricated via Wafer Bonding and Etch Back, Journal of Vacuum Science & Technology B (Microelectronics and nanometer Strcutures), vol.20, no. 2, pp. 725-727 (2002). The approach incorporated a strained Si etch stop layer just below the relaxed SiGe transfer layer. After wafer bonding to an oxidized Si handle wafer, the backside of the SiGe transfer wafer is thinned via grinding followed by a KOH etch that removes Si and stops on the 20% Ge region. At this point, the surface of the transferred layer is still quite rough. The next step involves the use of a SiGe etch to remove the excess SiGe and stop on the strained Si layer, leaving a much smoother surface, with precise control over the thickness of the transferred layer. In the above work, a SiGe etch of acetic acid, hydrogen peroxide, and hydrofluoric acid (3:2:1) was found to have a high selectivity and to stop on the strained. A remaining challenge was the presence of pitting once the strained Si was exposed to the etching solution.

There is a need, therefore, for a system and method for forming smooth, uniform thickness SiₓGe_{y} materials having a low defect density and improved bond strength at low temperatures. There is further a need to provide a smooth and robust etch stop layer.

### SUMMARY OF THE ILLUSTRATED EMBODIMENTS

In accordance with an embodiment, the invention provides a method for creating a transferred composite. The method includes the steps of depositing a buffer structure on a first substrate; depositing a bonding structure comprising of at least one layer of a strained semiconductor material on the buffer structure, wafer bonding an exposed surface of the bonding structure to a second substrate to form a wafer bonded pair; and removing the first substrate and at least a portion of the buffer structure. The layer of a strained semiconductor material in the bonding structure has a thickness that is greater than the equilibrium critical thickness of said strained semiconductor material; the equilibrium critical thickness is defined as the thickness beyond which misfit dislocations would form at the lower interface of the strained semiconductor material layer closer to the substrate, at temperatures greater than approximately 800° C. in accordance with an embodiment of the invention.

In other embodiments, at least one misfit dislocation segment may be formed at a strained semiconductor interface closest to the substrate, and in further embodiments, the layer of strained semiconductor material has a thickness smaller than a thickness at which the threading dislocation density exceeds 5×10⁶ cm⁻³.

### BRIEF DESCRIPTION OF THE ILLUSTRATED EMBODIMENTS

The following description may be further understood with reference to the accompanying drawings in which:

FIG. 1 shows an illustrative diagrammatic graphical representation of misfit and threading dislocations in a strained Si on relaxed SiGe structure;

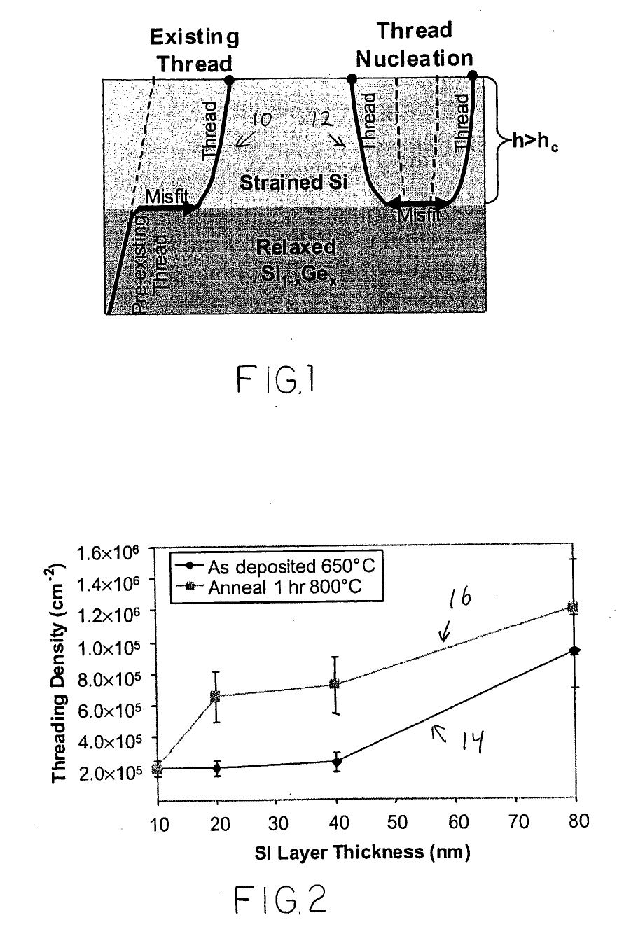

FIG. 2 shows an illustrative diagrammatic graphical view of dislocation density versus strained Si thickness for different temperatures;

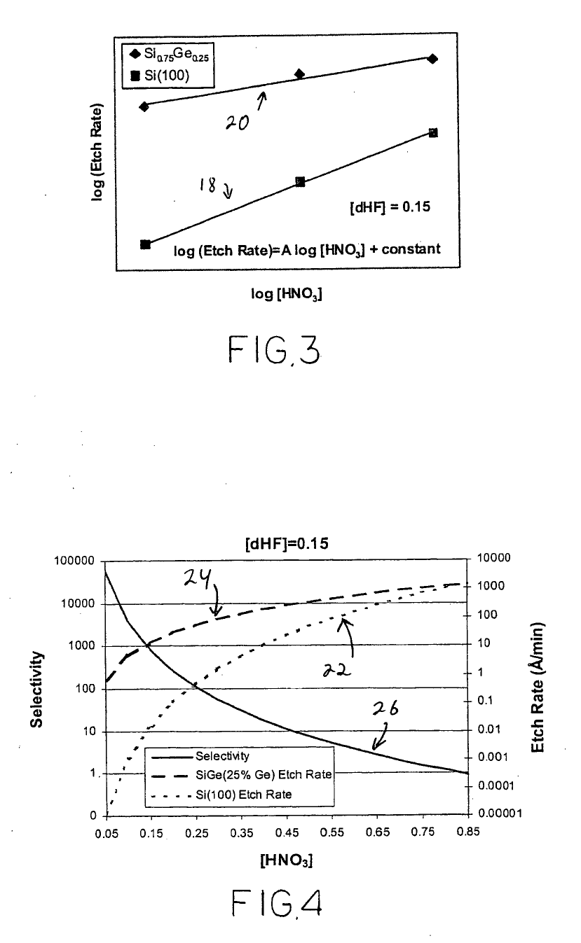

FIG. 3 shows an illustrative diagrammatic graphical view of a log-log plot of etch rate versus HNO₃ concentration for different materials;

FIG. 4 shows an illustrative diagrammatic graphical view of selectivity and etch rate versus HNO₃ for different materials;

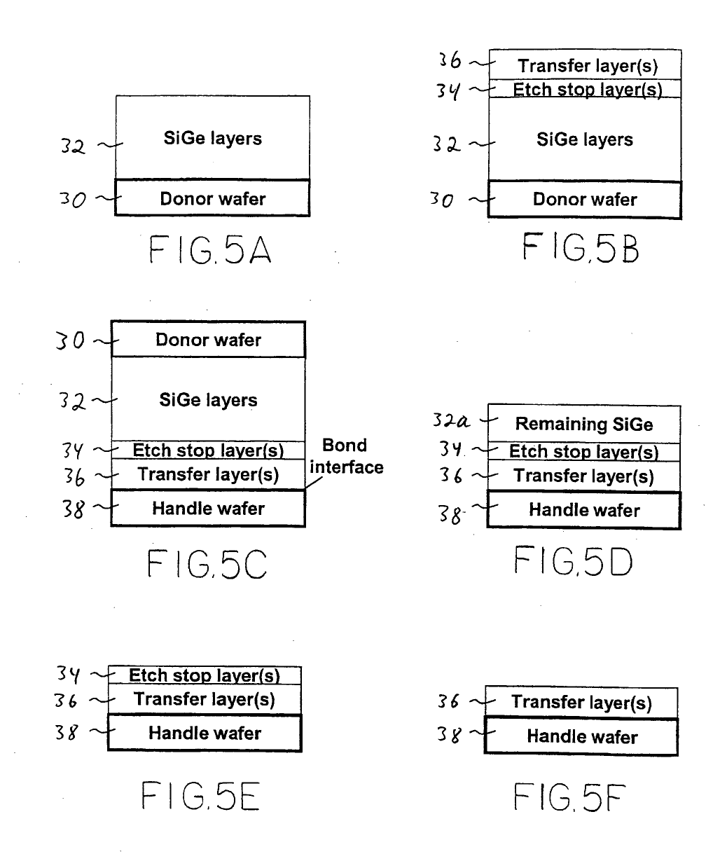

FIGS. 5A-5F show illustrative diagrammatic views of process flow diagrams of a fabrication process in accordance with an embodiment of the present invention employing backside material removal;

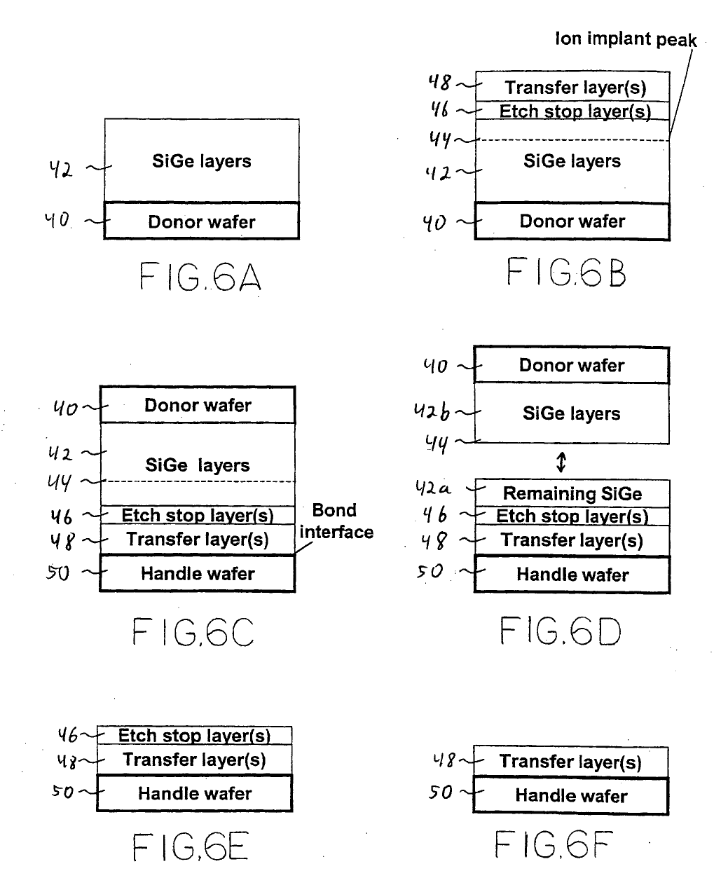

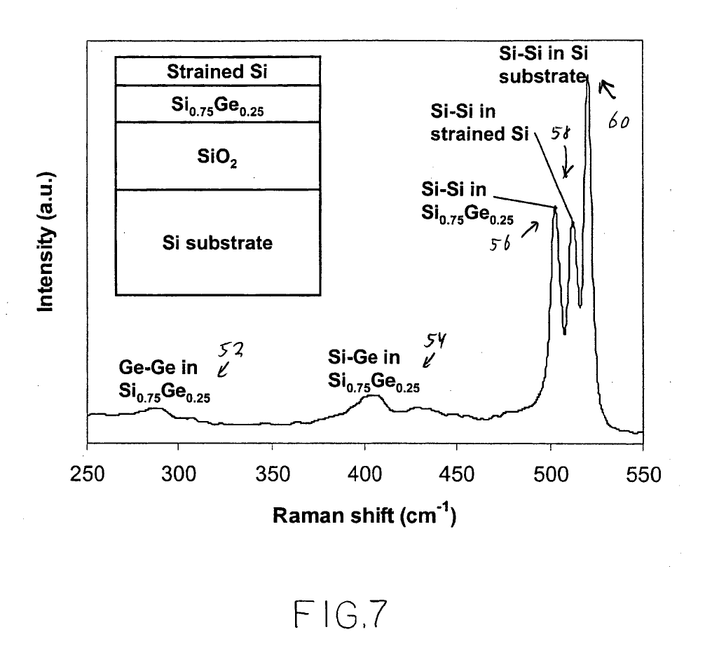

FIGS. 6A-6F show illustrative diagrammatic views of process flow diagrams of a fabrication process in accordance with another embodiment of the invention employing delamination via implantation; and

FIG. 7 shows an illustrative diagrammatic view of a Raman spectrum of a SiGe on insulator with strained Si on the surface.

The drawings are shown for illustrative purposes and are not to scale.

### DETAILED DESCRIPTION OF THE ILLUSTRATED EMBODIMENTS

The invention provides a method for fabricating smooth, uniform thickness, low defect density, monocrystalline silicon-germanium (SiGe) alloys, Si, Ge or combinations thereof on any desired substrate, using wafer bonding. In an embodiment, the method employs the deposition of a buffer structure, comprised of SiGe layers, Si or Ge on a first substrate (the donor wafer). Note that it is possible to start with a first substrate that has the same lattice constant as the buffer structure being deposited. If surface roughness prohibits wafer bonding, the surface is planarized. Next, the bonding structure is deposited onto the buffer structure, comprising of etch stop layer(s) and optional transfer layer(s). After wafer bonding to a second substrate (the handle wafer), layer transfer is achieved via either backside material removal, or via delamination by implantation. The exposed SiGe is then selectively etched stopping on the etch stop(s), yielding a smooth layer (composed of the etch stop and optional transfer layers) with a uniform thickness across the handle wafer, named a transferred composite. The etch stop layer(s) may then be optionally removed using a selective etch, leaving only the transfer layer(s) on the handle substrate. The present invention permits the incorporation of relatively thick etch stop layers, plasma activated low temperature wafer bonding, and improved selective SiGe etching. The buffer structure may be used to alter the lattice constant, or may have the same lattice constant as the first substrate in various embodiments.

In the present invention, at least one layer in the bonding structure is thicker than the equilibrium critical thickness of the strained semiconductor layer. Strained layers relieve their strain via the formation of misfit dislocations at the lower interface closer to the substrate, a process here forth named relaxation. These dislocations only form when the total energy of the system (including the strain energy plus dislocation formation energy) is reduced by their introduction. Dislocations forms in a strained semiconductor layer thicker than the equilibrium critical thickness (h_{c}), which is a function of the strain level and elastic properties of the material system. The equilibrium critical thickness is defined as the thickness beyond which misfit dislocations would form at the lower interface of the strained semiconductor material layer closer to the substrate, at temperatures greater than approximately 800° C. Beyond the equilibrium critical thickness, strain is partially relieved (i.e. relaxed) via the formation of misfit dislocations at the interface of the strained layer closer to the underlying substrate. It has been found that if strained layers are grown at low temperatures, significant strain relaxation (via misfit dislocation formation at the lower strained layer interface) and a significant increase in threading dislocation density (dislocation segments running from lower interface to the surface) does not occur for strained layers thicker than the equilibrium critical thickness due to kinetic barriers for nucleating dislocations as discussed in more detail below.

The present invention provides a variety of methods as discussed below for transferring high quality, uniform layers of monocrystalline SiGe, Si, Ge, or combinations thereof onto any desired substrate. The methods may differ, for example, in the way the layers are transferred to the second substrate (the handle substrate). One such method employs backside material removal of the first substrate (the backside removal approach), while another may employ delamination via ion implantation (the delamination approach).

The backside removal approach consists of (a) depositing layers of monocrystalline Si—Ge, Si or Ge on a first substrate (for example, either a Si or Ge substrate) to possibly alter the lattice constant on the exposed wafer surface, as compared to the starting surface of the first substrate, while keeping the threading dislocation density at a minimum; (b) planarizing the surface of the deposited Si—Ge layers, if surface roughness prohibits wafer bonding; (c) depositing a bonding structure (comprised of one or more etch stop layers and optional transfer layer(s) consisting of Si—Ge alloys, Si, Ge or combinations thereof; (d) wafer bonding the surface of the first substrate (also called a donor wafer) to a second substrate (also called a handle wafer) forming what is called a wafer bonded pair; (e) material removal of the backside of the first substrate; and (f) material removal of the remaining Si—Ge material stopping on the etch stop layer(s) (where the resulting structure is called a transferred composite). After layer transfer, a selective chemical etch can be used to remove excess SiGe and controllably stop on the etch stop, allowing for the creation of a smooth, uniform thickness, high quality transferred layer. In addition, due to the presence of the etch stop, the final transferred layer can be as thin as desired.

The delamination approach consists of (a) depositing layers of monocrystalline Si—Ge, Si or Ge on a first substrate (for example, either a Si or Ge substrate) to possibly alter the lattice constant on the exposed wafer surface; (b) planarizing the surface of the deposited Si—Ge layers, if surface roughness prohibits wafer bonding; (c) depositing a bonding structure (comprised of one or more etch stop layers and optional transfer layer(s) consisting of Si—Ge alloys, Si, Ge or combinations thereof; (d) implanting ions into the surface of the first wafer; (e) wafer bonding the surface of the first substrate (also called a donor wafer) to a second substrate (also called a handle wafer) forming what is called a wafer bonded pair; (f) splitting of the wafer bonded pair at the implant depth; and (g) material removal of the remaining Si—Ge material stopping on the etch stop layer(s) (where the resulting structure is called a transferred composite).

An aspect of the invention is the optional removal of the etch stop layer after the SiGe material removal step. Device layers may then be grown onto the surface, if they are not already built into the bonding structure.

The invention provides further improvements on the etch stop thickness, wafer bonding and selective etch. These improvements increase the robustness, flexibility, and yield of the process.

In certain embodiments, the invention concerns the use of strained relatively thick etch stop layers (thicker than the equilibrium critical thickness) deposited at a low temperature. The strained layers grown via this method may be made thicker than the equilibrium critical thickness without the introduction of any new threading or misfit dislocations, and hence no substantial relaxation. This thicker etch stop layer may act as an improved etch stop, while possibly serving as a functional device layer in the transferred composite. The use of these relatively thick etch stop layers are helpful in providing the selective etch sufficient thickness on which to stop, and thereby improving the robustness and yield of the process.

Such relatively thick etch stop layers (such as strained Si) that are thicker than the equilibrium critical thickness are also useful in fabrication of semiconductor devices because they allow for greater flexibility in design. Beyond the equilibrium critical thickness, strained Si layers deposited on relaxed Si₁₋ₓGeₓ relieve their strain (i.e. relax) via the introduction of misfit dislocation segments at the strained Si/S₁₋ₓGeₓ interface. Misfit segments may either be created by the glide of existing threading dislocations, or by the nucleation of two new threads, as shown at 10 in FIG. 1, or by the nucleation of new threading segments as shown at 12 in FIG. 1. Nucleation possesses a larger kinetic barrier than glide, and hence is substantially reduced at low temperatures. Irrespective of magnitude, both processes are suppressed by kinetic barriers at low temperatures, allowing for the deposition of relatively thick strained Si layers that are thicker than the equilibrium critical thickness. These relatively thick layers do not contain significant misfit dislocations and hence exhibit little or no strain relaxation. In addition, they also exhibit no increase in threading dislocation density.

Low-temperature strained Si growth experiments have been conducted to determine the thickness (beyond the equilibrium critical thickness) that a strained Si layer may be grown before misfit and additional threading dislocations form. The strained Si for these experiments was grown on Si_{0.75}Ge_{0.25} virtual substrates (which are relaxed SiGe graded layer structures on Si substrates that create a larger lattice constant at the wafer surface, as compared to the lattice constant of the underlying Si substrate) using UHV-CVD at 650° C. Samples with strained Si thicknesses of 10, 20, 40 and 80 nm were deposited. To test the thermal stability of the layers, samples were annealed for 1 hour at 800° C. in a N₂ ambient.

Etch-pit-density (EPD) measurements were used to determine the threading dislocation density for each sample. EPD results for the 40 nm strained Si sample reveal an increase in threading dislocations, but did not reveal any misfit dislocations. In particular, FIG. 2 shows a summary of the EPD threading densities for as-grown and annealed samples at 14 and 16 respectively. The as-deposited 10, 20 and 40 nm strained Si samples had threading densities that were almost identical to that of the underlying substrate (Si_{0.75}Ge_{0.25}). This indicates that at the growth temperature of 650° C. and for thicknesses less than 40 nm, the thermal energy (for the given strain energy) is not high enough to nucleate a substantial number of new threading dislocations. In contrast, the 80 nm strained Si had a large number (about 6×10⁵ cm⁻²) of newly nucleated threading dislocations due to the larger strain energy present in the structure (since strained energy scales with layer thickness). In other embodiments, the growth temperature may be below 650° C., e.g., may be 550° C. In certain embodiments, therefore, at least one misfit dislocation may be formed at the strained semiconductor interface closest to the substrate. In further embodiments the layer of strained semiconductor material has a thickness smaller than the thickness at which the threading dislocation density exceeds 5×10⁶ cm⁻³, and preferably is smaller than the thickness at which the threading dislocation density exceeds 1.2×10⁶ cm⁻³.

Annealing the samples at 800° C. for 1 hour dramatically influenced the threading dislocation density. In all samples with strained layers greater than the critical thickness (16 nm), annealing led to the nucleation of new threading dislocations. With respect to threading dislocations, therefore, relatively thick strained layers with thicknesses less than 40 nm were found to be acceptable for certain applications as long as they are not exposed to temperatures greater than the growth temperature.

Although low threading densities are important for high quality device material, an additional concern is the degree of relaxation in relatively thick layers. The relaxation is directly related to misfit density, and may be estimated using plane-view transmission electron microscopy (PVTEM). PVTEM images for the 40 nm strained Si samples demonstrate the presence of misfit dislocation in the as-grown sample, and the introduction of a substantial number of additional misfit segments after the 800° C. anneal. The misfit density ρ_{md} may be used to calculate the plastic strain δ (i.e., strain relieved due to misfits) using

δ=b_{eff}ρ_{md}

where b_{eff} is the effective Burgers vector given by b_{eff}=aₛᵢ/\sqrt{2} and aₛᵢ is the lattice constant of Si. In addition, the strain due to the difference in lattice mismatch is given by f=(a_{f}-aₛ)/a_{f} where a_{f} and aₛ are the film and substrate lattice constants (e.g., f=0.0106). The total mismatch strain is in turn distributed between elastic strain ε, and the plastic strain due to misfit dislocations δ, hence f=ε+δ. Finally, the degree of strained Si relaxation is calculated using

$$relaxation factor = \frac{δ}{f}$$

Table 1 below shows misfit densities and strain relaxation factors for various strained Si samples where the misfit density ρ_{md} is measured using PVTEM and the misfit spacing S, plastic strain δ and relaxation factors are calculated based on ρ_{md}. The as-grown samples were deposited at 650° C., and then annealed for 1 hour at 800° C.

TABLE 1

| | Strained Si | | | | |
|---|---|---|---|---|---|
| | Thickness | ρ md | | | Relaxation |
| | (nm) | (cm⁻¹) | S (μm) | δ | Factor (%) |
| As-Grown | 10 | 0 | 0 | 0 | 0 |
| Annealed | 10 | 0 | 0 | 0 | 0 |
| As-Grown | 20 | 0 | 0 | 0 | 0 |
| Annealed | 20 | <9.1 × 10² | >11 | <3.5 × 10⁻⁵ | <0.3 |
| As-Grown | 40 | 2.2 × 10⁴ | 0.45 | 8.5 × 10⁻⁴ | 8 |
| Annealed | 40 | 5.2 × 10⁴ | 0.19 | 2.0 × 10⁻³ | 19 |

No dislocations were detected for the as-grown and annealed 10 nm strained Si samples, nor for the as-grown 20 nm strained Si sample, indicating the absence of any significant strain relaxation. In contrast, after annealing, the 20 nm strained Si sample had a sparse number of misfit dislocations, yielding a relaxation factor of at most 0.3%, hence the layer is still fully strained even after 1 hour at 800° C. In contrast, the as-grown 40 nm strained Si sample already had a detectable misfit array, with a corresponding relaxation of about 8%. The presence of a misfit array with no significant increase in threading density above the base-line density implies that during growth at 650° C., relaxation for the 40 nm strained Si occurs via glide of existing threading dislocations, rather than by nucleation of new threads. Annealing the 40 nm strained Si sample at 800° C. for 1 hour led to a doubling of the misfit density, implying a relaxation factor of 19%. Since relaxation is reasonably low and threading dislocation density is minimal for the 40 nm strained Si layer when high anneal temperatures are avoided (i.e. temperatures greater the growth temperature), this layer thickness could be used as a thick etch-stop layer in the proposed process.

In the present demonstration, an etch-stop thickness of 30 nm strained Si was employed, which is still thicker than the equilibrium critical thickness of strained Si on relaxed Si_{0.75}Ge_{0.25}, which is approximately 12 nm. A structure chosen for process development and characterization had a 30 nm strained Si stop with a 30 nm relaxed Si_{0.75}Ge_{0.25} transfer layer. The structure was grown at 550° C., and had no detectable misfit or additional threading dislocations. After wafer bonding and delamination via implantation (which transferred a 870 nm thick layer), the sample was die-sawed into 1×1 cm² squares, and various SiGe etches were used to remove excess Si_{0.75}Ge_{0.25}, while stopping on the strained Si.

Another aspect of the present invention, therefore, concerns the use of low temperature wafer bonding of the SiGe virtual substrate to the desired handle substrate in certain embodiments. The low temperature bonding process employs a plasma activation prior to wafer bonding, which yields a strong bond strength and no intrinsic interface bubbles after annealing. Both wafers may be activated, yielding optimal bond strength, but if the SiGe surface is susceptible to plasma damage that may effect the device layers, the handle wafer need only be plasma activated to achieve substantial bond strength enhancement compared to when no activation is employed. The low temperature bonding process is important when bonding layers that are thicker than the equilibrium critical thickness, which might relax due to exposure to a high temperature post-bond anneal. In addition, the low temperature bonding procedure is crucial if inter-diffusion of layers is significant at higher temperatures.

In further embodiments, the invention involves the use of a selective material removal process to remove excess SiGe after wafer bonding and to stop on the etch stop layer. Any selective etch process, whether wet or dry may be used. A generic selective etch that may be employed consists of an oxidizer and an oxide stripping agent. For example, low temperature wet oxidation (steam oxidation) followed by a dilute HF oxide strip may be employed, and has been found to selectively oxidize Si_{0.75}Ge_{0.25} faster than Si. Possible wet selective etches are solutions of: (1) hydrogen peroxide, hydrofluoric acid, and a dilutant, (2) nitric acid, hydrofluoric acid, and a dilutant, (3) ammonium hydroxide, hydrogen peroxide, and a dilutant, (3) ammonium hydroxide, hydrogen peroxide, hydrofluoric acid, and a dilutant, (4) ammonium hydroxide, hydrogen peroxide, hydrofluoric acid, ammonium fluoride, and a dilutant, or (5) sulfuric acid, nitric acid, hydrofluoric acid, and a dilutant. It has been discovered that the hydrogen peroxide and hydrofluoric etch caused pitting of the etch stop layer once it was exposed. In contrast, the nitric acid and hydrofluoric etch do not create any etch pits upon stopping on the etch stop.

For example, by changing both the oxidizing agent and reducing the HF concentration, it has been further discovered that a HNO₃:dHF:HAc etch (where dHF is dilute HF composed of 1% HF and 99% water) may be used that has the necessary selectivity with a fast SiGe etch rate with no indication of preferential dislocation etching. The etch rate depends strongly on the constituent concentrations. Based on chemical kinetics, etch rates follow a power-law dependence given by

Etch rate=k[HNO₃]^{A}[dHF]^{B}

where [HNO₃] and [dHF] represent HNO₃ and dHF concentrations, and k, A and B are materials dependent constants. To optimize the SiGe etch rate and selectivity, the etch rate of Si(100) and relaxed Si_{0.75}Ge_{0.25} virtual substrates were measured for various concentrations of HNO₃ and dHF. The data was then fit to determine k, A and B for Si and Si_{0.75}Ge_{0.25}. FIG. 3 shows a log-log plot of etch rate versus HNO₃, at constant [dHF]=0.15, used to fit the A constant for Si as shown at 18 and for Si_{0.75}Ge_{0.25} as shown at 20. Fitting a line to each data set allows for the extraction of A for Si and Si_{0.75}Ge_{0.25} etching, and similar fits allowed for the extraction of B and k.

A plot showing etch rates and selectivity is presented in FIG. 4 where the etch rate for Si is shown at 22 and the etch rate for Si_{0.75}Ge_{0.25} is shown at 24. The selectivity is also shown at 26 in FIG. 4 scaled along the left side axis. For Si and relaxed Si_{0.75}Ge_{0.25}, the fitting parameters were A_{Si}=6.6, B_{Si}=3.7, K_{Si}=5.0×10⁵ nm/min, and A_{SiGe}=2.7, B_{SiGe}=1.4, and K_{SiGe}=3.2×10³ nm/min. The fitting parameters allowed for the calculation of both the etch rates and the selectivity over a wide range of constituent concentrations. The selectivity was given by the relaxed Si_{0.75}Ge_{0.25} etch rate over the Si rate. As shown in FIG. 4, the calculated selectivity and etch rates with dHF held constant at 15%, [dHF]=0.15. As a function of decreasing [HNO₃], the Si etch rate decreases faster than the Si_{0.75}Ge_{0.25} etch rate (as may be seen from FIG. 3), leading to increased selectivity for lower HNO₃ concentrations. The trade-off for attaining this extremely high selectivity (for low [HNO₃]) is a significant decrease in the Si_{0.75}Ge_{0.25} etch rate.

In certain applications, [HNO₃]=0.45 and [dHF]=0.15 may yield an acceptable selectivity of about 11 and a relaxed Si_{0.75}Ge_{0.25} etch rate of 26 nm/min. The amount of Si_{0.75}Ge_{0.25} that may need to be removed may be, for example, 820 nm thick, implying a projected time of about 32 min. A higher selectivity may be attained using lower HNO₃ concentrations, but the corresponding etch rate would be too slow for the removal of the thick Si_{0.75}Ge_{0.25} layer. For example, solutions with [HNO₃]=25 may have a selectivity of about 110, but a Si_{0.75}Ge_{0.25} etch rate of only 5 nm/min. For a Si_{0.75}Ge_{0.25} removal thickness of 820 nm, the etch rate implies an estimated etch time of almost 3 hours, which is inappropriate for certain applications. On the other hand, since excess Si_{0.75}Ge_{0.25} thickness is determined solely by the implant depth, the thickness may be readily reduced by design. Given that after delamination, the peak-to-valley roughness is on the order of 100 nm, a safe lower limit would be an implant depth no closer than 100 run from the etch-stop layer. In that case, the etch time using the highly selective [HNO₃]=0.25 etch would only be about 20 min, allowing for the effective use of etching solutions with a very high selectivity of 100 or greater. This trade-off between selectivity and removal rate applies to all removal processes, and can be obtained by varying the concentration of the etching chemicals or gases. In this case, we have found based on our data that a wide range of acceptable selectivity can be obtained with HNO₃ concentrations ranging from 10% to 60% (by volume).

Another aspect of the invention is that an additional material (such as oxide, nitride, oxy-nitride, or silicon) may be deposited or grown on the bonding layer of the first substrate, prior to the wafer bonding in further embodiments. If surface roughness inhibits wafer bonding, the surface of the deposited material may be planarized.

Further, the invention also provides that the second substrate, onto which the SiGe is transferred, may be any material that possesses suitable properties for the desired application in other embodiments. Oxidized silicon, quartz, or glass substrates are examples of some possible substrates that have important electronic and optical isolation properties, but the proposed process is not limited to these. The bonding structure layers may be transferred onto any desired substrate.

The low threading dislocation defect density that may be achieved in accordance with certain embodiments of the invention is crucial for fabricating high quality devices on the substrates, and the ability to layer transfer the bonding structure layers onto any desired substrate allows for further optimization of device properties. In addition, uniform layer thickness and smoothness is crucial when dealing with devices that require very thin layers on a given substrate.

In particular, FIGS. 5A-5F show process flow diagrams of an exemplary fabrication process described in the present invention, employing backside material removal. In FIG. 5A a monocrystalline first substrate 30 (donor wafer) is used for the deposition of SiGe, Si or Ge layers 32 (named a buffer structure). The substrate 30 can be a monocrystalline Si substrate with the desired orientation, or it can be any other semiconductor substrate (for example, a Ge substrate) that has the required lattice parameter for the SiGe layers that will be deposited. In the preferred case when a Si substrate is used, the deposited SiGe is not lattice matched, and hence dislocations form to relieve the strain when the thickness of the SiGe exceeds the critical thickness. To minimize the number of threading dislocations (which terminate at the surface and interfere with device performance), the deposited SiGe consists of a graded layer system where the Ge content is gradually increased in each subsequent layer. The process allows the SiGe to relax and attain its equilibrium lattice constant by reusing existing threading dislocations to relieve additional strain. The method is crucial for creating relaxed layers of SiGe with low threading dislocation density. This relaxed surface layer of low defect density SiGe, dubbed a virtual substrate, is an ideal starting layer for the fabrication of many advanced electronic devices, including strained surface channel and buried channel MOSFETs.

Typically, the graded SiGe layers are deposited using chemical vapor deposition (CVD) at elevated temperatures ranging from about 750° C. to 900° C., with a grading rate of about 10% Ge per μm, and with SiGe layers of about 200 nm. Preferably the deposition temperature is 900° C., since higher temperatures have been found to allow for the highest dislocation velocity and hence the best use of existing threading dislocations to relax the graded layers. In addition, growth rates are faster at higher temperatures.

The difficulty with this SiGe grading process stems from the creation of surface roughness, dubbed cross-hatch roughness. Such rough surface roughness inhibits the wafer bonding, and must be eliminated. A surface planarization step is hence needed to make the wafer bonding possible. This planarization consists of any method that reduces roughness, while not removing too much material. Examples of such methods are chemical mechanical polishing, ion beam smoothing, or cluster ion beam smoothing, to name just a few.

As shown in FIG. 5B, thin etch stop layer(s) 34 and the desired transfer layers 36 are deposited on the first substrate 30; the structure comprised of 34 and 36 is called the bonding structure. The etch stop layer(s) can consist of one or more layers consisting of SiGe alloys, Si, Ge or combinations thereof, and the thickness of the individual layers that comprise the etch stop can range in thickness from 0.1 nm to 300 nm, and is preferably about 20 to 40 nm. In addition, the transfer layers 36, although depicted as one layer in the diagram, can consist of multiple layers. In particular, it can contain device layers consisting of SiGe alloys, Si, Ge or combinations thereof, ranging in thickness from 0.1 nm to 500 nm. The desired thickness depends on the intended application; preferably, for fully-depleted MOSFETs the thickness of the semiconductor layer on the oxide should be 30 nm or less. In such a case, it is advantageous to use the etch stop layers as the active device layer, without any transfer layer in the bonding structure; for example a bonding structure consisting of only a strained Si etch stop with no transfer layer and can be bonded directly to the handle wafer, allowing for the layer transfer of strained Si directly onto an insulating substrate.

The etch stop layer(s) and bonding structure layer(s) can be deposited using a variety of techniques, including, but not limited to, chemical vapor deposition CVD, or molecular beam epitaxy MBE. The deposition is preferably done using low temperature CVD at a temperature between 400° C. and 750° C., which limits the amount of inter-diffusion experienced by the thin layers. Preferably the deposition is done at 650° C. or lower, which not only limits inter-diffusion, but also allows for strained layers to be grown thicker than the equilibrium critical thickness without the introduction of substantial threading of misfit dislocations. This implies that the layers can be thicker than the equilibrium critical thickness without relaxing via misfit dislocation creation. These thicker layers may be crucial for the creation of multiple device layers, or more robust, thicker etch stop layers.

Optionally, another material can be deposited onto layer 36. If the resulting surface is not smooth enough to insure strong bonding, the surface of the deposited material can then be planarized. For example, the deposited material can be silicon dioxide, doped silicon dioxide, oxy-nitride, or nitride. The preferred material is silicon dioxide, but this depends on the material properties required by the intended structure. For example, a layer that exhibits no flow at elevated temperatures may be preferred, which would imply the use of nitride or oxy-nitride.

A second substrate 38 is provided, and can consist of any material(s) with the needed electrical, optical, or thermal properties for the final application. For example, the second substrate can be Si, oxide on Si, quartz, or glass. The preferred substrate 38 for SGOI or SSOI fabrication is monocrystalline Si substrate with a layer of silicon dioxide on the surface. This layer of silicon dioxide can either be thermally grown or deposited on the Si substrate.

As shown in FIG. 5C, the first substrate 30 and the second substrate 38 are cleaned and then bonded to form a wafer bonded pair. Cleaning can be performed using a variety of chemistries, including a standard RCA, or piranha clean. If the surface has exposed SiGe, the RCA1 bath etches the surface, and hence is modified by replacing it with a piranha solution. The cleaning process can leave the surface of the wafers, either hydrophilic or hydrophobic, largely dependent on whether a final HF dip is employed on the semiconductor surfaces. Hydrophilic wafer surfaces imply stronger bonding when a low temperature anneal (<800° C.) is employed, and hence are preferred. In addition, plasma activation can be employed just prior to bonding, followed by a water bath. The activation creates dangling bonds at the oxide surfaces (native, grown or deposited oxide) and increases the bond strength. If device layer surface damage due to plasma activation is an issue, only the second substrate 38 need be plasma treated, which still results in an improvement in bond strength. After room temperature wafer bonding, the bond strength of the wafer pair can be increased by annealing at a temperature between about 100° C. and 1000° C., preferably at a temperature of about 400° C. This low temperature bonding is crucial if the etch stop layer(s) and bonding structure layer(s) are thicker than their respective equilibrium critical thickness, and hence will relax at higher temperatures.

As shown in FIG. 5D, the backside of the first substrate 30 is then removed leaving being only a portion of the SiGe layers 32a. Preferably, the backside of the first substrate is thinned using grinding, reducing the thickness of the first substrate down to a thickness in the range of 10 μm to 200 μm, preferably about 100 μm is left. Since the preferred substrate 30 is Si, the remaining Si is removing by employing a Si etch, for example, either KOH or TMAH. These etches remove Si and stop on the 20% Ge content region of the relaxed SiGe graded layers, with a very high selectivity. The composite shown in FIG. 5D may be referred to as a transferred composite, which is further processed as shown in FIGS. 5E and 5F. Each of the composites shown in FIGS. 5D-5F is referred to as a transferred composite.

As shown in FIG. 5E, a SiGe etch is now used to etch away the remaining SiGe and stop on the etch stop layer(s), creating what is called a transferred composite. For example, if the etch stop layer is 20 to 30 nm of thick strained Si on a relaxed Si_{0.75}Ge_{0.25} layer, then any SiGe etch that does not attack Si appreciably is acceptable. Preferably, the SiGe etch should have a selectivity of about 10 or more. Possible wet etches are: (1) hydrogen peroxide, hydrofluoric acid, and a dilutant, (2) nitric acid, hydrofluoric acid, and a dilutant, (3) ammonium hydroxide, hydrogen peroxide, and a dilutant, (3) ammonium hydroxide, hydrogen peroxide, hydrofluoric acid, and a dilutant, (4) ammonium hydroxide, hydrogen peroxide, hydrofluoric acid, ammonium fluoride, and a dilutant, or (5) sulfuric acid, nitric acid, hydrofluoric acid, and a dilutant. Another possible selective etching process is the use of low temperature (less than 750° C.) wet (steam) oxidation followed by a dilute HF oxide strip.

As shown in FIG. 5F, the etch stop layer(s) can now be optionally removed, if they interfere with the desired application. Preferably, in the case of a strained Si etch stop, an etch that is selective to Si and does not etch the underlying layer can be used. If the underlying layer is SiGe, a low temperature KOH or TMAH etch can be used to controllably remove the strained Si etch stop, while not damaging the SiGe underneath, leaving behind the transferred layers on the second substrate. If required by the application, additional device layers can now be deposited onto the transferred layer 103.

FIGS. 6A-6F show process flow diagrams of an exemplary fabrication process in accordance with another embodiment of the present invention, employing delamination via implantation. All the material layers and the majority of the process steps are identical to the process described by FIGS. 5A-5F. The first difference is in the step shown in FIG. 2B, where after the deposition of the etch stop layer(s) 46 and the transfer layer(s) 48 (where the combined layers are called the bonding structure), ions are implanted into the surface of substrate 40, with a peak 44 below or on the etch stop layer(s). Typically, hydrogen ions are implanted with an energy ranging from 5 to 200 keV, and a dose ranging from about 5×10¹⁶ H/cm² to 10¹⁷ H/cm². A preferred implant depth of about 870 nm is attained using H₂ ions with an energy of 200 keV, and a dose of 4×10¹⁶ H₂/cm²=8×10¹⁶ H/cm².

The wafers are then bonded (creating a wafer bonded pair) using the same procedure as described for FIG. 5C, except that in this embodiment, the post-bond anneal causes the wafers to split at the ion implant depth. In the case of hydrogen ion implantation, the splitting is due to pressure exerted by the formation of hydrogen bubbles at the peak location. The annealing temperature required for splitting depends on the Ge content, and ranges between room temperature and 600° C. The higher the Ge content, the lower the required delamination temperature. Preferably, for Si_{0.75}Ge_{0.25}, an anneal at 550° C. for 3 hrs is sufficient to cause wafer splitting. Although annealing at elevated temperatures is a feasible method for causing splitting, the above invention is not limited to just approach. Another possible technique involves room temperature delamination along a strained layer onto which the ion peak is designed is lie, induced by the initiation of crack by an external source.

As shown in FIG. 6D the first substrate 40 is split at the implant peak transferring a portion of layer 42, named layer 42a, in addition to layers 46 and 48, onto the second substrate 50. Layer 42a has a thickness in the range of 0 nm to 1000 nm, preferably a thickness of about 150 nm is ideal, since it reduces the etch time required in subsequent selective etching shown in FIG. 6E. A thinner 42a layer is also preferable, since slower etch chemistries with extremely high selectivity can be employed, while still achieving reasonable etch time due to the small amount of material being removed. Note that the invention could also be applied by requiring that the implant peak lies directly on the etch stop layer. In such an embodiment, delamination would occur along the etch stop and layer 42a would not be present, this represents the case where layer 42a has a thickness of 0 nm. The composite shown in FIG. 6D may also be referred to as a transferred composite, which is further processed as shown in FIGS. 6E and 6F. Each of the composites shown in FIGS. 6D-6F is referred to as a transferred composite.

As shown in FIG. 6F, the etch stop layers can now be optionally removed, leaving behind the transferred layers on the second substrate 50. The procedure and possible options at this step are the same as those described for FIG. 5F.

The above descriptions of the invention detail how to create smooth, uniform thickness, low defect density, monocrystalline silicon-germanium (SiGe) alloy, Si, Ge, or combinations thereof on any desired substrate. Next, some specific applications of the invention are presented. These examples merely provide a best mode to achieve layer transfer of low dislocation density SiGe layers, Si, Ge, or combinations thereof, and are not meant the limit the general scope of the invention.

### EXAMPLE 1

This example deals with the use of delamination via implantation to achieve the transfer of uniform thickness, low defect density, monocrystalline, relaxed silicon-germanium (SiGe) on an insulating substrate, allowing for the creation of SGOI or SSOI substrates.

A relaxed Si_{0.75}Ge_{0.25} graded buffer structure was grown on 100 mm Si(100) wafers using ultra high vacuum chemical vapor deposition (UHVCVD). The deposition was done at a temperature of 900° C., with a grading rate of 10% Ge per μm, with SiGe layers having a thickness of 200 nm, and cap layer of 3 μm thick relaxed Si_{0.75}Ge_{0.25}. The threading dislocation density was determined to be about 2×10⁵ cm⁻², using etch pit density. Atomic force microscopy reveals that the surface is quite rough, with a peak-to-valley depth of about 25 nm. To achieve wafer bonding, the surface is planarized using a 15 min chemical mechanical polishing step, which removes about 2 μm of relaxed Si_{0.75}Ge_{0.25}, and achieves a smooth surface with 0.4 nm rms roughness. The resulting substrate, having a smooth relaxed SiGe surface is referred to as the SiGe virtual substrate.

This smooth SiGe virtual substrate is then prepared for another UHVCVD growth to deposit the bonding structure. This deposition is performed at a low temperature of 550° C., to ensure minimal inter-diffusion, and allowing for layers thicker than their equilibrium critical thickness to be deposited. The layers consist of 100 nm of Si_{0.75}Ge_{0.25} that buries any contaminants, about 30 nm of strained Si as an etch stop, followed by about 30 nm of Si_{0.75}Ge_{0.25} for a transfer layer. Although the strained Si layer is thicker than the equilibrium thickness of Si on relaxed Si_{0.75}Ge_{0.25}, misfit dislocations do not form, and the layer remains fully strained, due to the low growth temperature, that inhibits misfit dislocation creation. The exact choice of these layers and their thickness depends on the final desired device layers on the buried oxide, but the proposed general process embodies all possible choices. For example, the relaxed Si_{0.75}Ge_{0.25} transfer layer may easily be omitted from the growth sequence allowing for strained Si to be bonded directly to the buried oxide. In addition, multiple stop layers may be employed to increase the robustness of the stop process. Most importantly, relatively thick strained layers in the bonding structure may be grown thicker than the equilibrium critical thickness, without relaxing the layer via misfit formation as discussed above, nor generating any new threading dislocations.

Hydrogen ions are then implanted into the surface of the SiGe virtual substrate containing the etch stop and transfer layers. In this example H₂⁺ ions were used with an energy of 200 keV and a dose of 4×10¹⁶ H²/cm², giving an implant peak at a depth of about 870 nm.

Another Si substrate is then thermally oxidized for a layer of SiO₂, with a thickness of about 500 nm. This substrate is referred to as the handle wafer. The handle substrate and the donor wafer (containing the bonding structure layers on a SiGe virtual substrate) are then cleaned and prepared for wafer bonding. The pre-bond clean for the donor wafer (containing SiGe) begins with of a 3 min piranha clean, a dump rinse, a 1 min 50:1 HF dip, a final dump rinse, and a spin dry. Then both the donor and handle wafer, are exposed to a 4 min piranha clean, a dump rinse, followed by a final spin dry. The wafers are then activated using a 1 Torr oxygen plasma for 1 min, and the wafers are placed in a water bath for 10 min. All wafer surfaces were found to be hydrophilic after this treatment.

The donor wafer (with the buffer structure and bonding structure) and the handle wafer are then directly bonded at room temperature, and annealed at 300° C. for 3 hours to strengthen the bond, and then at 550° C. for 3 hrs to cause splitting of the wafers at the implant peak. This process resulted in the transfer of about 870 nm from the donor SiGe virtual substrate. The surface of the transferred material had a peak-to-valley roughness of about 100 nm.

The final step in this example, then involved the removal of the remaining SiGe stopping on the strained Si etch stop layer. To achieve this, a solution of nitric acid, acetic acid, and dilute hydrofluoric acid (dHF, which consists of 50:1 DI water: HF), HNO₃: HAc: dHF, was employed as a SiGe etch. The selectivity and SiGe etch rate were optimized by fitting experimental etch rates to determine the variation over a wide range of solution concentrations, as shown in FIG. 4, where the dilute HF concentration was kept constant at 0.15 and the nitric concentration was varied. A reasonable selectivity of 11 and a Si_{0.75}Ge_{0.25} etch rate of 28.5 nm/min was found using a solution composed of 45:40:15 (HNO₃: HAc: dHF). A fresh batch of solution was mixed every 20 min to keep the etch rate constant, otherwise it was found that the etch rate slowed considerably. The etch stopped on the strained Si layer, leaving a significantly smoother surface.

Note that if the thickness of the SiGe that needed removal was thinner, a lower nitric concentration could have been employed, yielding a much higher selectivity, while still retaining a reasonable etch time. For example, if the remaining SiGe layer was only 100 nm thick, then using [HNO₃]=0.25 would yield a selectivity of 100 with an etch rate of about 10 nm/min, and hence a total etch time of still only (100 nm)/(10 nm/min)=10 mm.

Raman spectroscopy using a 514.5 nm laser source was performed on the transferred composite structure comprising of the strained Si etch stop and relaxed Si_{0.75}Ge_{0.25} on oxide. As shown in FIG. 7, the spectrum has three peaks in the 500 to 520 cm⁻¹ range, corresponding to Si—Si bonds in the relaxed Si_{0.75}Ge_{0.25} transfer layer as shown at 56, in the strained Si etch stop layer as shown at 58, and in the Si substrate as shown at 60. Using the location of these peaks, the concentration and strain of the Si_{0.75}Ge_{0.25} transfer layer and the strain in the Si etch stop layer can be deduced. The strained Si layer is found to be tensile, with a strain of 1.02%, corresponding to a fully strained Si layer on a relaxed Si_{0.75}Ge_{0.25} virtual substrate. The demonstrates that although the original strained Si layer thickness of 30 nm is greater than the equilibrium critical thickness of about 12 nm, relaxation via misfit generation does not occur due to the low growth temperature for the bonding structure and the low bonding temperature. This implies that the 30 nm Si_{0.75}Ge_{0.25} transfer layer, deposited on the strained Si layer, must be fully relaxed, as was verified by the Raman spectra calculations.

The above shows one possible method of fabrication for SGOI or SSOI substrates using delamination in accordance with the invention. The same process could have been performed without the 30 nm relaxed Si_{0.75}Ge_{0.25} transfer layer, which would have lead to the fabrication of a SSOI substrate with strained Si directly on oxide. This may facilitate the fabrication of ultra-thin (<30 nm) semiconductor layers on insulator, for fully depleted MOSFETs on SSOI substrates.

Another possible modification would have been the use of a multiple layer etch stop; for example, a multiple etch stop could consist of a strained Si layer followed by an ultra-thin, relaxed Si_{0.75}Ge_{0.25} layer. This structure could then be capped with the desired device layers, for example, a strained Si layer. After bonding and delamination, the selective etch would stop on the strained Si etch stop layer. A low temperature KOH etch could then be employed to remove the strained Si etch stop while stopping on the ultra-thin Si_{0.75}Ge_{0.25}. A highly selective SiGe etch could then be used to strip the ultra-thin Si_{0.75}Ge_{0.25} layer. The final structure would then consist of only the device layers (e.g., strained Si) on the insulating substrate.

### EXAMPLE 2

This next example deals with the use of backside material removal to achieve the transfer of uniform thickness, low defect density, monocrystalline, relaxed Si—Ge, Si, Ge, or combinations thereof on an insulating substrate, allowing for the creation of SGOI or SSOI substrates:

The process steps are exactly the same as those outlined in Example 1, except that in this case, ion implantation is not performed prior to wafer bonding. In this example, the wafers are directly bonded at room temperature, and annealed at 400° C. for 2 hours, resulting in a bond strength that is sufficient to withstand wafer grinding. The backside grinding process left about 100 μm of the SiGe virtual substrate. The wafer pair is then etched for about 6 hrs in a solution of KOH (30% by wt) at a temperature of 60-65° C., to remove the remaining Si and controllably stop on the 20% Ge region of the graded buffer.

The remaining steps are identical to those performed in Example 1, where a SiGe etch is used to remove excess SiGe and stop on the strained Si etch stop layer, yielding the same transferred composite structure as described in Example 1.

The above description and examples represent only a small subset of possible embodiments, and many variations are possible. Those skilled in the art will appreciate that numerous modifications and variations may be made to the above disclosed embodiments without departing from the spirit and scope of the invention.

What is claimed is:

1. A method of creating a transferred composite comprising at least one layer of a strained semiconductor material, said method comprising the steps of:
depositing a buffer structure on a first substrate;
depositing a bonding structure including at least one layer of a strained semiconductor material on said buffer structure, said layer of strained semiconductor material having a thickness that is greater than the equilibrium critical thickness of said layer of strained semiconductor material;
wafer bonding an exposed surface of said bonding structure to a second substrate to form a wafer bonded pair; and
removing the first substrate and at least a portion of the buffer structure.

2. The method as claimed in claim 1, wherein at least one misfit dislocation segment has formed at a strained semiconductor interface closest to the substrate.

3. The method as claimed in claim 2, wherein the layer of strained semiconductor material has a thickness smaller than a thickness at which the threading dislocation density exceeds 5×10⁶ cm⁻³.

4. The method as claimed in claim 1, wherein said bonding structure is formed at a low temperature.

5. The method as claimed in claim 1, wherein said bonding structure includes an etch stop layer.

6. The method as claimed in claim 1, wherein said step of removing said first substrate and at least a portion of the buffer structure involves selective removal of said substrate by reducing the thickness of said wafer bonded pair.

7. The method as claimed in claim 1, wherein said method further includes the step of implanting ions into an area within said bonding structure that divides said bonding structure into first and second portions.

8 The method as claimed in claim 1, wherein said step of removing said first substrate and at least a portion of the buffer structure involves delamination of said wafer bonded pair.

9. The method as claimed in claim 1, wherein said bonding structure includes an exposed surface that is planarized.

10. The method as claimed in claim 1, wherein said bonding structure does not significantly flow at temperatures required for device processing.

11. The method as claimed in claim 1, wherein said bonding structure includes at least one of oxide, nitride and oxy-nitride.

12. The method as claimed in claim 1, wherein said buffer structure includes SₓGe_{y}.

13. The method as claimed in claim 1, wherein said buffer structure is a relaxed layer of semiconductor material.

14. The method as claimed in claim 1, wherein said buffer structure is comprised of graded relaxed layers.

15. The method as claimed in claim 1, wherein said buffer structure is comprised of SiGe graded relaxed layers.

16. The method as claimed in claim 1, where said bonding structure includes at least one layer of strained Si.

17. The method as claimed in claim 5, wherein said etch stop layer consists of a strained Si—Ge alloy, Si, Ge or combinations thereof.

18. The method as claimed in claim 5, wherein said method further includes the step of removing said etch stop layer.

19. The method as claimed in claim 1, wherein said bonding structure includes at least one device layer.

20. The method as claimed in claim 1, wherein at least one of said first or second substrates is treated with a plasma before bonding.

21. The method as claimed in claim 1, wherein said step of bonding includes a post-bond anneal.

22. The method as claimed in claim 1, wherein said step of bonding includes a post-bond anneal at a temperature not greater than the deposition temperature of the bonding structure.

23. The method as claimed in claim 1, wherein the removal of said at least a portion of said buffer structure is performed using an oxidizer and an oxide stripping agent.

24. The method as claimed in claim 1, wherein the removal of said at least a portion of said buffer structure is performed using low temperature wet oxidation, at a temperature less than 750° C., followed by a dilute HF etch to strip the oxide.

25. The method as claimed in claim 1, wherein the removal of at least a portion of said buffer structure is performed using a wet chemical etch, consisting of active chemicals and dilutant chemicals.

26. The method as claimed in claim 25, wherein the wet chemical etch is a solution of hydrogen peroxide, hydrofluoric acid, and a dilutant.

27. The method as claimed in claim 25, wherein the wet chemical etch is a solution of nitric acid, hydrofluoric acid, and a dilutant.

28. The method as claimed in claim 25, wherein the wet chemical etch is a solution of ammonium hydroxide, hydrogen peroxide, and a dilutant.

29. The method as claimed in claim 25, wherein the wet chemical etch is a solution of ammonium hydroxide, hydrogen peroxide, hydrofluoric acid, and a dilutant.

30. The method as claimed in claim 25, wherein the wet chemical etch is a solution of ammonium hydroxide, hydrogen peroxide, hydrofluoric acid, ammonium fluoride, and a dilutant.

31. The method as claimed in claim 25, wherein the wet chemical etch is a solution of sulfuric acid, nitric acid, hydrofluoric acid, and a dilutant.

32. The method as claimed in claim 25, wherein the dilutant is water.

33. The method as claimed in claim 25, wherein the dilutant is acetic acid.

34. The method as claimed in claim 25, wherein the dilutant is a mixture of water and acetic acid.

35. The method as claimed in claim 1, wherein regions of the wafer are masked, exposing some areas of a surface, and in exposed regions, material is removed stopping on device layers.

36. The method as claimed in claim 1, wherein the first substrate is monocrystalline Si.

37. The method as claimed in claim 1, wherein the first substrate is monocrystalline Ge.

38. The method as claimed in claim 1, wherein the second substrate includes at least one of Si, oxide on Si, quartz, and glass.

39. The method as claimed in claim 1, wherein said step of removing the first substrate and at least a portion of the buffer structure involves the use of KOH or TMAH as an etching agent.

40. The method as claimed in claim 1, wherein said step of removing the first substrate and at least a portion of the buffer structure involves the use of dHF as an etching agent.

41. A method of creating a semiconductor structure bonded to a handle substrate comprising at least one layer of a strained semiconductor material, said method comprising the steps of:
depositing a buffer structure on a first substrate;
depositing a bonding structure including at least one layer of a strained semiconductor material on said buffer structure;
wafer bonding an exposed surface of said bonding structure to a second substrate to form a wafer bonded pair;
removing the first substrate and at least a portion of the buffer structure; and
removing additional material with a etching solution containing HNO₃.

42. The method as claimed in claim 41, wherein said etching solution containing HNO₃ has a HNO₃ concentration of 10% to 60% by volume.

43. A method of creating a transferred composite comprising at least one layer of a strained semiconductor material, said method comprising the steps of:
depositing a buffer structure on a first substrate;
depositing a bonding structure including at least one layer of a strained semiconductor material on said buffer structure, wherein at least one misfit dislocation segment has formed at a strained semiconductor interface closest to the substrate;
wafer bonding an exposed surface of said bonding structure to a second substrate to form a wafer bonded pair; and
removing the first substrate and at least a portion of the buffer structure.

44. The method as claimed in claim 43, wherein the layer of strained semiconductor material has a thickness smaller than a thickness at which the threading dislocation density exceeds 5×10⁶ cm⁻³.

45. The method as claimed in claim 43, wherein the layer of strained semiconductor material has a thickness smaller than a thickness at which the threading dislocation density exceeds 1.2×10⁶ cm⁻³.

46. A wafer bonded composite comprising:
a buffer structure on a first substrate;
a bonding structure including at least one layer of a strained semiconductor material on said buffer structure, said layer of strained semiconductor material having a thickness that is greater than the equilibrium critical thickness of said layer of strained semiconductor material; and
a second substrate wafer bonded to an exposed surface of said bonding structure to form a wafer bonded pair.

47. The wafer bonded composite as claimed in claim 46, wherein said bonding structure includes an etch stop layer.

48. The wafer bonded composite as claimed in claim 46, wherein said bonding structure includes at least one of oxide, nitride and oxy-nitride.

49 The wafer bonded composite as claimed in claim 46, wherein said buffer structure includes SiₓGe_{y}.

50 The wafer bonded composite as claimed in claim 46 wherein said buffer structure is a relaxed layer of semiconductor material.

51 The wafer bonded composite as claimed in claim 46 wherein said buffer structure is comprised of graded relaxed layers.

52 The wafer bonded composite as claimed in claim 46 wherein said bonding structure includes at least one layer of strained Si.

53 A wafer bonded composite comprising:
a buffer structure on a first substrate;
a bonding structure including at least one layer of a strained semiconductor material on said buffer structure, wherein at least one misfit dislocation segment has formed at a strained semiconductor interface closest to the substrate; and
a second substrate wafer bonded to an exposed surface of said bonding structure to form a wafer bonded pair.

54 The wafer bonded composite as claimed in claim 53 wherein the layer of strained semiconductor material has a thickness smaller than a thickness at which the threading dislocation density exceeds 5×10⁶ cm⁻³.

55 The wafer bonded composite as claimed in claim 54 wherein the layer of strained semiconductor material has a thickness smaller than a thickness at which the threading dislocation density exceeds 1.2×10⁶ cm⁻³.

56 A transferred composite comprising:
a bonding structure including at least one layer of a strained semiconductor material on said buffer structure, said layer of strained semiconductor material having a thickness that is greater than the equilibrium critical thickness of said layer of strained semiconductor material; and
a second substrate wafer bonded to an exposed surface of said bonding structure to form a wafer bonded pair.

57 The transferred composite as claimed in claim 56 wherein said transferred composite further includes a buffer structure.

58 The transferred composite as claimed in claim 56 wherein said bonding structure includes an etch stop layer.

59 The transferred composite as claimed in claim 56 wherein said bonding structure includes at least one of oxide, nitride and oxy-nitride.

60. The transferred composite as claimed in claim 56 wherein said buffer structure includes SiₓGe_{y}.

61 The transferred composite as claimed in claim 56 wherein said buffer structure is a relaxed layer of semiconductor material.

62 The transferred composite as claimed in claim 56 wherein said buffer structure is comprised of graded relaxed layers.

63 The transferred composite as claimed in claim 56 wherein said bonding structure includes at least one layer of strained Si.

64. A transferred composite comprising:
a bonding structure including at least one layer of a strained semiconductor material on said buffer structure, wherein at least one misfit dislocation segment has formed at a strained semiconductor interface closest to the substrate; and
a second substrate wafer bonded to an exposed surface of said bonding structure to form a wafer bonded pair.

65 The transferred composite as claimed in claim 64 wherein said transferred composite further includes a buffer structure.

66. The transferred composite as claimed in claim 64 wherein the layer of strained semiconductor material has a thickness smaller than a thickness at which the threading dislocation density exceeds 5×10⁶ cm⁻³.

67. The transferred composite as claimed in claim 65, wherein the layer of strained semiconductor material has a thickness smaller than a thickness at which the threading dislocation density exceeds 1.2×10⁶ cm⁻³.
